(19) United States
(12) Patent Application Publication
(10) Pub. No.: US 2015/0323567 A1
(43) Pub. Date: Nov. 12, 2015

(54) RESISTOR FOR DETECTING CURRENT

(71) Applicant: KOA CORPORATION, Ina-shi (JP)

(72) Inventors: Hiromitsu Kitahara, Ina-shi (JP); Takayuki Yamabe, Ina-shi (JP)

(73) Assignee: KOA CORPORATION, Ina-shi (JP)

(21) Appl. No.: 14/701,633

(22) Filed: May 1, 2015

(30) Foreign Application Priority Data
May 9, 2014 (JP) 2014-097766

(51) Int. Cl. G01R 1/20; G01R 19/15

(52) U.S. Cl. CPC G01R 1/203; G01R 19/15

(57) ABSTRACT

Provided is a metal plate resistor, which is able to be manufactured easily, and which has heat dissipation characteristics with a small variation, while maintaining small and compact structure. The resistor includes a resistance body (11) consisting of a metal material, a terminal portion (12) electrically conducting to the resistance body, a mold body (20) for covering the resistance body, a guide member (16A) formed on a portion on a surface of the resistance body except a central portion thereof, and a heat equalizing plate (14) disposed on the guide member and adhered at least to a central portion of the resistance body by an adhesive for absorbing heat generated in the resistance body. The guide member (16A) is preferably formed by pre-molding and disposed on a mount surface side of the resistance body. The heat equalizing plate (14) preferably overwraps on the terminal portions (12).

### TECHNICAL FIELD

The invention relates to a resistor for detecting current, and particularly relating to a metal plate resistor including a resistance body consisting of a metal material.

### BACKGROUND ART

Recently, electronic controlling is advancing in the electronic equipments and the demand for resistors, which are able to detect high current in high accuracy, is increasing. Especially, the demand for the metal plate resistors having resistance body consisting of a metal material is increasing, since according to the resistors, low resistance value and low resistance temperature coefficient can be obtained, and high current can be detected in high accuracy.

In the metal plate resistors for detecting high current, however there are problems that reliability decreases basing on heat generation in the resistance body consisting of a metal material and detection accuracy decreases basing on resistance temperature coefficient. Thus, high heat dissipation characteristics are required, and two prior art documents are known for countermeasures against heat generation and heat dissipation of the resistance body in the metal plate resistor.

The prior art document 1 (WO 2009/005108) discloses that a heat dissipation plate is disposed close to and parallel to plate-shaped resistance body, terminal portions at both ends of the resistance body are formed to be surface mountable, and terminal portions at both ends of the heat dissipation plate are formed to be surface mountable. According to both kinds of terminal portions, generated heat by resistance body can be further dissipated to mount board through the heat dissipation plate. However, while miniaturization of the equipment progresses, it requires four terminal portions, that is, two terminal portions of the resistor and two terminal portions of the heat dissipation plate, to be surface-mounted, and there is a problem that the usage is limited.

The prior art document 2 (Japanese laid-open patent publication 2009-289770) discloses a structure that a base plate for heat dissipation is adhered to resistance body consisting of metal film via insulation layer. However, when the clearance between the base plate and the resistance body varies, there is a possibility that variation may happens in effect of heat dissipation. Therefore, it is necessary to control thickness of adhesive material in manufacturing process, and there is a problem that manufacturing is difficult.

### SUMMARY OF INVENTION

### Technical Problem

The invention has been made basing on above-mentioned circumstances. Therefore, object of the invention is to provide a metal plate resistor, which is easy to manufacture, and which has heat dissipation characteristics with a small variation, while maintaining small and compact structure.

### Solution to Problem

The resistor of the invention includes a resistance body consisting of a metal material, a terminal portion electrically conducting to the resistance body, a mold body for covering the resistance body, a guide member formed on a portion on a surface of the resistance body except a central portion thereof, and a heat equalizing plate disposed on the guide member and adhered to at least central portion of the resistance body by an adhesive for absorbing the heat generated in the resistance body.

According to the invention, since the heat equalizing plate is disposed on the guide member formed on a surface of the resistance body, and is adhered to at least central portion of the resistance body by an adhesive, the heat equalizing plate can be bonded to the resistance body easily with highly accurate clearance by the adhesive. Therefore, variation of clearance between the resistance body and the heat equalizing plate can be small, and the metal plate resistor having excellent heat dissipation characteristics with a small variation can be manufactured easily.

### BRIEF DESCRIPTION OF DRAWINGS

FIG. 1A is a perspective view, which shows upper side of the resistor of first embodiment of the invention.

FIG. 1B is a perspective view, which shows bottom side of the resistor.

FIG. 2A is a plan view, which shows the resistance body and the pre-mold body of the resistor of bottom side.

FIG. 2B is a plan view, which shows the resistance body and the pre-mold body of the resistor of upper side.

FIG. 2C is a cross-sectional view along AA line in FIG. 2A and FIG. 2B.

FIG. 3A is perspective views of the resistor in the manufacturing process, which shows step of bonding terminal portions 12 to both ends of resistance body 11. Left view shows bottom side, and right view shows upper side.

FIG. 3B Similarly, FIG. 3B shows step of forming pre-mold body 16 on bottom side of the resistance body and pre-mold body 18 on upper side of the resistance body.

FIG. 3C Similarly, FIG. 3C shows step of coating adhesives 13 on bottom side of the resistance body 11.

FIG. 3D Similarly, FIG. 3D shows step of adhering heat equalizing plate 14 on bottom side of the resistance body 11.

FIG. 3E Similarly, FIG. 3E shows step of forming mold body 20 to cover the resistance body 11 and the heat equalizing plate 14. Left view shows bottom side of the resistor, and right view shows upper side of the resistor.

FIG. 4A is a perspective view, which shows step of forming pre-mold body 16 and positioning guide 17 on bottom side of the resistance body 11 in manufacturing process of the resistor of second embodiment of the invention.

FIG. 4B Similarly in manufacturing process of the resistor, FIG. 4B shows step of adhering the heat equalizing plate 14 on bottom side of the resistance body 11

FIG. 5 In manufacturing process of the resistor of third embodiment of the invention, FIG. 5 is a perspective view, which shows step of forming pre-mold body 16 having positioning guide 16D on bottom side of the resistance body 11.

### DESCRIPTION OF EMBODIMENTS

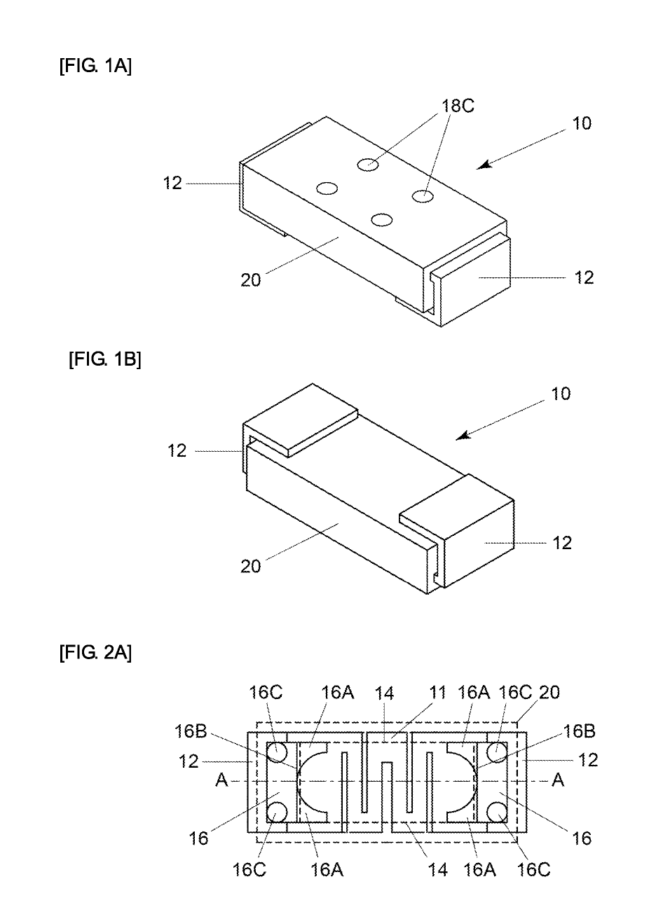

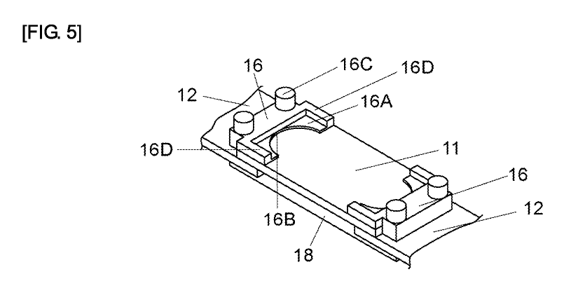

Embodiments of the invention will be described below with referring to FIG. 1A through FIG. 5. Like or corresponding parts or elements will be denoted and explained by same reference characters throughout views.

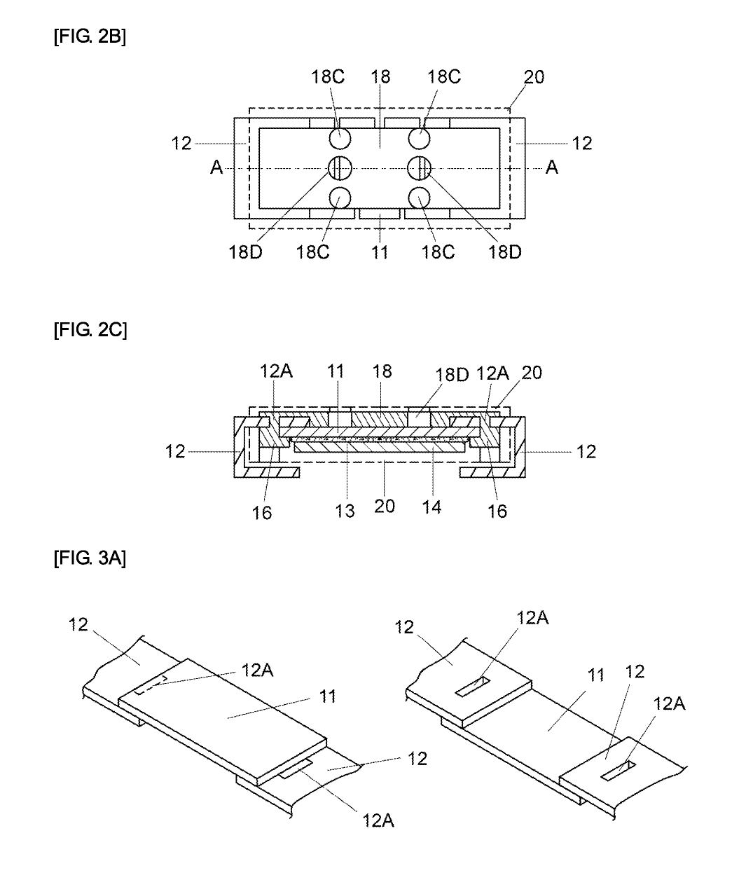

FIGS. 1A-1B show an outside of the metal plate resistor of first embodiment of the invention, and FIGS. 2A-2C show internal structure thereof. The resistor includes a resistance body 11 consisting of a metal material such as Cu—Ni system, Cu—Mn—Ni system, Ni—Cr system, Fe—Cr system, etc., a pair of terminal portions 12 consisting of a metal material such as Cu, electrically connecting to the resistance body, having higher conductivity than the resistance body, and a mold body 20 for covering the resistance body.

The resistance body 11 and the terminal portion 12 may be integrally formed consisting of one piece of resistive material. In the case, exposed portion out of mold body 20 becomes the terminal portion 12, and a portion between the terminal portions 12, 12 becomes the resistance body 11. Plating such as Sn may be given to the terminal portions 12, 12. The terminal portion 12 is folded along end face and bottom face of the mold body, and the structure of the terminal portions becomes surface mountable. And, top of boss 18C has been exposed on upper surface of the mold body 20.

The resistance body 11 includes serpentine cutting at central portion thereof, and the portion becomes heat generating center. Inside of the resistor 10, heat equalizing plate 14, which is able to absorb the heat generated in the resistance body, is adhered to at least central portion of the resistance body 11 by adhesive 13 (see FIG. 2C). The heat equalizing plate 14 consists of a plate material of Cu, Al, etc., of excellent thermal conductivity. For an example, an aluminum plate with anodic oxidation coating thereon may be used. The heat equalizing plate 14 is disposed on mount surface side (bottom side) of the resistance body, and overwraps on terminal portion 12.

Accordingly, when local heat generation occurs at central portion of the resistance body 11 by high current, the generated heat is absorbed into heat equalizing plate 14, and conducting to terminal portions 12, where heat dissipation is well, thus high heat dissipation effect can be obtained. Further, since heat equalizing plate 14 is disposed at mount surface side (bottom side) of resistance body, it is preferable that heat generated in resistance body 11 is easy to conduct to substrate. In the embodiments, examples where the heat equalizing plate is disposed at mount surface side are shown, however, it may be disposed opposite to mount surface side (that is, upper side), and it may be disposed at both sides, that is, bottom side and upper side.

Further, it is preferable that the adhesive 13 is resin system adhesive including filler of good insulative characteristics and good thermal conductivity characteristics. Therefore, the heat generated in the resistance body can be well conducted to the heat equalizing plate.

Pre-mold body 16 including guide member 16A for disposing heat equalizing plate 14 at both ends is formed on bottom surface side of the resistance body 11 (see FIG. 2A). The guide member 16A for disposing heat equalizing plate 14 at both ends is made to be circular arc as shown in the figure to improve coating of the adhesive.

Here, the thickness of guide member 16A provides separation (clearance) between surface of resistance body 11 and surface of heat equalizing plate 14. And, end faces 16B of guide members 16A provide both end positions of heat equalizing plate 14 in length direction. Accordingly, heat equalizing plate 14 is disposed on guide member 16A, is positioned by end faces 16B, and is adhered at least, at central portion on the resistance body with high clearance accuracy. Thus, heat generation of resistance body 11 can be efficiently absorbed. Therefore, clearance between resistance body 11 and heat equalizing plate 14 can be kept constant, thus, excellent heat dissipation characteristics can be obtained stably with a small variation.

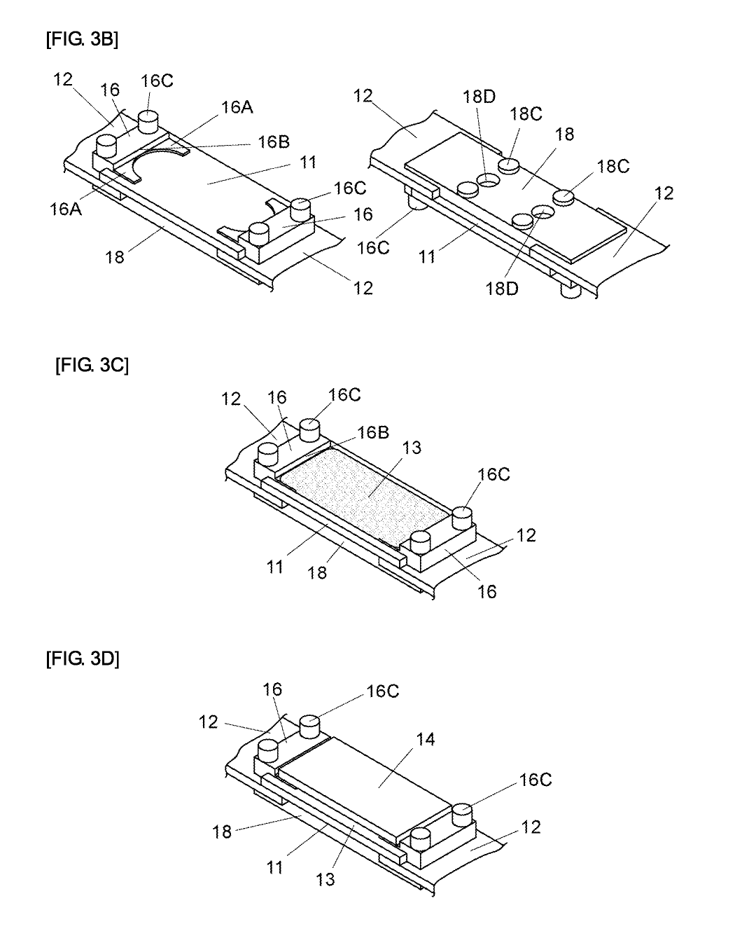

Pre-mold body 16 includes boss 16C, which positions bottom surface of exterior mold body 20 of resin. Further, pre-mold body 18 is formed on upper side of resistance body 11, and boss 18C is provided for positioning upper surface of exterior mold body 20 of resin (see FIG. 3B).

These pre-mold bodies 16, 18 are integrally formed via through holes 12A in the terminal portions 12 (see FIG. 2C). Thin resistance body 11 is sandwiched and held between pre-mold bodies 16, 18. And, resistance body 11 and heat equalizing plate 14 are positioned inside of exterior mold body 20. Accordingly, tops of boss 16C and 18C are exposed on surfaces of exterior mold body 20.

FIGS. 3A-3E shows manufacturing process of the resistor 10. First, as shown in FIG. 3A, terminal portions 12 are joined to both ends of resistance body 11. Joint may be formed by overwrapping end portions of resistance body 11 and terminal portion 12 and seam-welding them, or by abutting end faces of resistance body 11 and terminal portion 12 and laser welding them to form the joint. Terminal portion 12 includes a through hole 12A at vicinity of the joint to resistance body 11.

Next, as shown in FIG. 3B, pre-mold body 16 is formed on mount surface (bottom surface) side of resistance body 11, and pre-mold body 18 is formed on upper surface side of resistance body 11 each by pre-molding process. Pre-mold bodies 16 and 18 is integrally formed via through hole 12 formed in terminal portion 12. Concretely, when pre-mold bodies are formed, first, left-lower side pre-mold body 16 is formed by resin injected therein, next, upper side pre-mold body 18 is formed by resin going through the through hole 12A to back side (upper side), and then right-lower side pre-mold body 16 is formed by resin going through the through hole 12A to bottom side. Then, pre-mold bodies 16, 18 are integrally formed.

Here, an example that resin is injected through a through hole 12A from lower-side to upper-side is shown, however resin may be able to be injected from side of terminal portions 12 or resistance body 11 to upper and bottom side. Further, in case of resin injected from a side of resistance body 11, there is a possibility that resistance body 11 is transformed, thus it is preferable that resin shall be injected to upper and lower upon terminal portions 12.

By the process, the pre-mold body 16 including the guide member 16A, the end face 16B, and the boss 16C etc. is formed. Similarly, the boss 18C is formed on the pre-mold body 18. Since, resistance body 11, which is thin and easy to be transformed, is sandwiched and held between pre-mold bodies 16, 18 by the pre-molding process, it becomes easy for handling in the manufacturing process. Further, through holes 18D are made by metal mold for holding the resistance body when pre-molding. Then resistance body 11 is exposed from the through holes 18D.

Next, an adhesive 13 is applied between end faces 16B, 16B of pre-mold bodies 16, 16 as shown in FIG. 3C. Heat equalizing plate 14 having excellent thermal conductivity is disposed on guide members 16A, positioned by end faces 16B, adhered and heated to be hardened, and fixed. Therefore, clearance between resistance body 11 and heat equalizing plate 14 can be easily kept constant on all over the plate 14.

Guide member 16A is disposed at both ends of heat equalizing plate 14, and central portion of the plate 14 is fixed to central portion of resistance body 11 by the adhesive 13. Then heat generation portion of resistance body 11 is covered by heat equalizing plate 14 and the variation of the clearance between resistance body and heat equalizing plate becomes small. Therefore, the metal plate resistor, which has excellent heat dissipation characteristics with a small variation, can be manufactured easily.

Mold body 20 for covering resistance body 11 and heat equalizing plate 14 is formed by second molding process, as shown in FIG. 3E. Here, pre-mold bodies 16, 18 include bosses 16C, 18C, and while top of bosses is abutted to upper end and lower end inside of mold cavity, second molding process is carried out. Then while resistance body 11 and heat equalizing plate 14 are positioned inside thereof, mold body 20 can be easily formed.

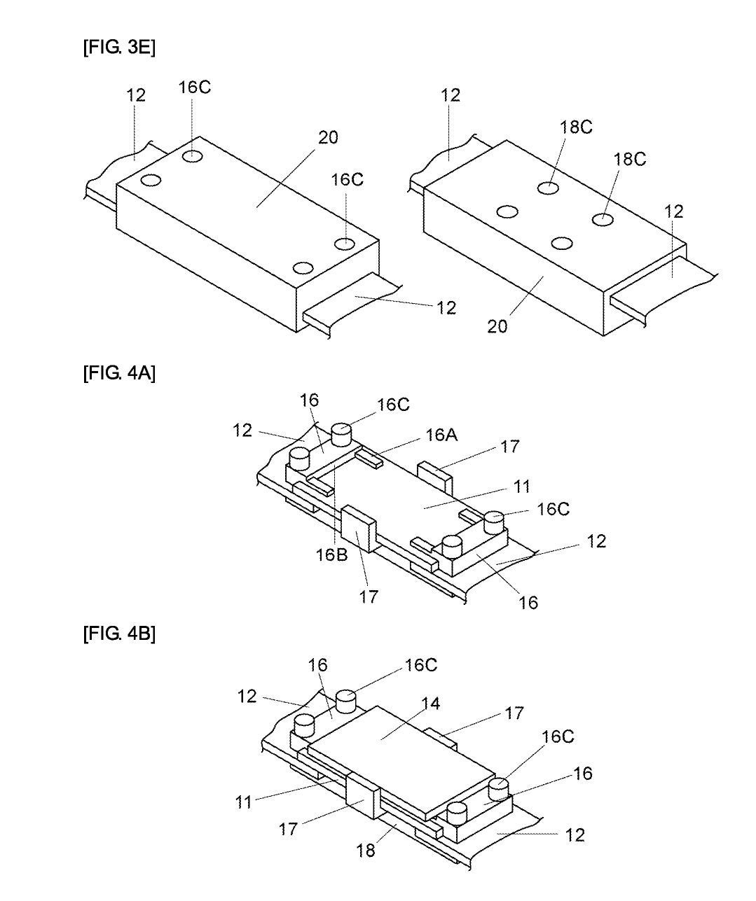

FIGS. 4A-4B shows manufacturing process of the resistor of second embodiment of the invention. In the embodiment, positioning guides 17 are formed for positioning heat equalizing plate 14 at both sides in width direction of resistance body 11 at roughly central portion thereof on mount surface side of resistance body 11 (see FIG. 4A). Here, pre-mold body 16 has guide member 16A, end face 16B, and boss 16C. The positioning guide 17 is formed as a portion of pre-mold body 18. Therefore, when adhering and fixing heat equalizing plate 14, the plate 14 can be easily positioned on resistance body 11 by end faces 16B in length-wise direction and by guides 17 in width-direction (see FIG. 4B).

FIG. 15 shows manufacturing process of the resistor of third embodiment of the invention. In the embodiment, pre-mold body 16 has positioning guide 16D at both sides in width direction of guide member 16A for positioning heat equalizing plate 14. And, in following process, an adhesive 13 is applied on surface of guide member 16A and resistance body 11 (see FIG. 3C), and heat equalizing plate 14 is adhered and fixed (see FIG. 3D).

Heat equalizing plate 14 is positioned at both ends thereof by positioning guides 16D and by end faces 16B, and it is prevented from the plate 14 getting out of position to width direction and length direction of resistance body 11. In the embodiment, since heat equalizing plate 14 is disposed on guide member 16A, a constant clearance to resistance body 11 corresponding to thickness of guide member 16A can be obtained all over the plate 14. It is similar to above-mentioned embodiments to be able to manufacture the metal plate resistor that has an excellent heat dissipation characteristic with a small variation easily.

Although embodiments of the invention has been explained, however the invention is not limited to above embodiments, and various changes and modifications may be made within scope of the technical concepts of the invention.

### INDUSTRIAL APPLICABILITY

The invention can be used for resistors for detecting current, especially for metal plate resistors.

1. A resistor for detecting current, comprising:
a resistance body consisting of a metal material;
a terminal portion electrically conducting to the resistance body;
a mold body for covering the resistance body;
a guide member formed on a portion on a surface of the resistance body except a central portion thereof; and
a heat equalizing plate disposed on the guide member and adhered at least to a central portion of the resistance body by an adhesive for absorbing heat generated in the resistance body.

2. The resistor for detecting current of claim 1, wherein the terminal portion consists of a metal, which has higher conductivity than the resistance body, and the heat equalizing plate overwraps on the terminal portions.

3. The resistor for detecting current of claim 1, wherein the heat equalizing plate is covered by the mold body.

4. The resistor for detecting current of claim 1, wherein the heat equalizing plate is disposed on mounting surface side of the resistance body.

5. The resistor for detecting current of claim 1, wherein the guide member is formed by pre-molding.
